(19) United States
(12) Patent Application Publication
(10) Pub. No.: US 2026/0312583 A1
(43) Pub. Date: Oct. 8, 2026

(54) CRYOGENIC HYBRID CONTROLLER FOR CONTROL OF MULTIPLE SUPERCONDUCTING QUBITS

(71) Applicant: Dell Products L.P., Round Rock, TX (US)

(72) Inventors: Tejinder Singh, Manotick (CA); Navjot Kaur Khaira, Manotick (CA)

(21) Appl. No.: 19/045,511

(22) Filed: Feb. 4, 2025

(51) Int. Cl. H03K 17/92; H03L 7/08

(52) U.S. Cl. CPC H03K 17/92; H03L 7/08

(57) ABSTRACT

The technology described herein is generally directed to a RSFQ (rapid single flux quantum) and CMOS (complementary metal oxide transistor)-based hybrid controller designed to operate at the 4K stage of a dilution refrigerator. The hybrid controller is configured to generate precise control pulses for interaction with multiple qubits by generating different local oscillator frequencies using phase locked loops driven by a common reference clock. Single flux quantum (SFQ)-based repeaters are employed at further cryogenic stages to ensure high-fidelity communication. Multiplexed qubit readout of measured quantum state information of the qubits can be via a shared microwave feedline. The measured quantum state information can be used by a cryogenic receiver for virtually immediate error correction, and or the quantum hardware can be integrated with classical systems for quantum state information feedback and error correction.

### BACKGROUND

As quantum computers scale up to incorporate large numbers of qubits, managing the control of qubits at cryogenic temperatures becomes increasingly challenging. While significant progress has been made in expanding the number of superconducting qubits, the complexity of the control and readout hardware has also grown.

### BRIEF DESCRIPTION OF THE DRAWINGS

The technology described herein is illustrated by way of example and not limited to the accompanying figures in which like reference numerals indicate similar elements and in which:

FIG. 1 is a representation of a group of superconducting qubits configured for readout using a hybrid controller based on RSFQ (rapid single flux quantum) and CMOS (complementary metal oxide transistor) technologies deployed in a dilution refrigerator, in accordance with various example embodiments and implementations of the subject disclosure.

FIGS. 2A, 2B and 3A are example superconducting qubit-related representations of in which qubit control is achieved through precisely-shaped microwave pulses (FIG. 2A) that induce arbitrary rotations on the Bloch sphere (FIG. 2B), in which the phase of the microwave signal (FIG. 3A) applied at the qubit's resonant frequency determines the angle of rotation on the XY-plane, in accordance with various example embodiments and implementations of the subject disclosure.

FIGS. 3B, 4A and 4B are example superconducting qubit-related representations showing how a qubit's state influences a resonator's frequency through dispersive coupling, allowing the qubit state to be inferred by measuring the magnitude and/or phase of a probing signal interacting with the resonator, in accordance with various example embodiments and implementations of the subject disclosure.

FIG. 5 is a representation of an example hybrid CMOS-and RSFQ-based processor addressing quantum storage devices arranged in an m×n array for readout via resonators, in accordance with various example embodiments and implementations of the subject disclosure.

FIG. 6 is a block diagram of an example four-by-four qubit array with addressable qubits, in accordance with various example embodiments and implementations of the subject disclosure.

FIGS. 7 and 8 comprise a block diagram showing an example of integration of classical control and an RSFQ and CMOS-based processor, with real-time feedback obtained from the measured quantum state information of qubits, in accordance with various example embodiments and implementations of the subject disclosure.

FIG. 9 is a block diagram of a quantum-classical interface showing a stack of elements for quantum computing, including qubit control layer, quantum programs, routing, and error correction systems, in accordance with various example embodiments and implementations of the subject disclosure.

FIG. 10 is a flow diagram showing example operations related to obtaining qubit measurement data based on a hybrid RSFQ and CMOS-based controller operating to output microwave signals to interact with qubits, in accordance with various example embodiments and implementations of the subject disclosure.

### DETAILED DESCRIPTION

The technology described herein is generally directed towards a hybrid controller with RSFQ (rapid single flux quantum) and CMOS (complementary metal oxide transistor)-based components, in which the hybrid controller is configured to operate in a dilution refrigerator, e.g., at the at the 4 Kelvin (4 K) stage. The hybrid controller can generate precise microwave control pulses for multiple qubits by generating different local oscillator (LO) frequencies using multiple phase locked loops (PLLs) driven by a common reference clock. As will be understood, the hybrid controller architecture described herein eliminates the current quantum computing approach of running individual electrical connections from the room temperature to every qubit.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics, and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some processing capacity limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

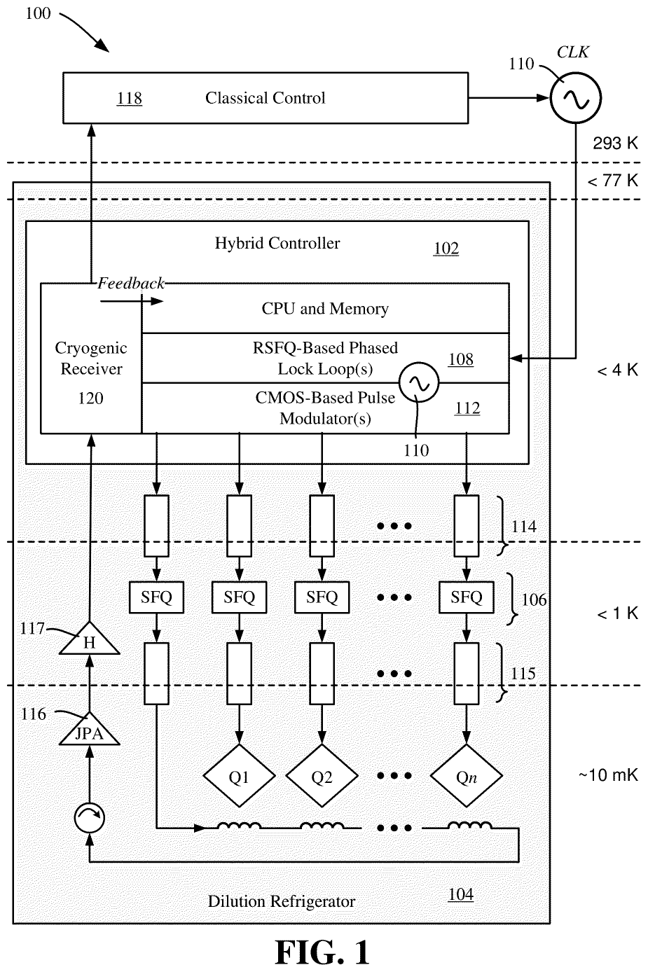

FIG. 1 is an example system 100 for readout of quantum state information from multiple superconducting qubits Q1-Qn using a hybrid controller 102 based on RSFQ and CMOS technologies operating in a dilution refrigerator 104 at <=4K. The system 100/architecture addresses the challenges of scaling quantum computers, by efficiently managing qubit control and readout within a cryogenic environment. The system 100/architecture is designed to reduce the number of control lines, minimize power dissipation, and ensure high-fidelity qubit operations. Single-flux quantum (SFQ) repeaters (collectively labeled 106) are deployed at the subsequent cryogenic temperature stage (e.g., <1 K) to ensure accurate timing and transmission of classical-type bitstreams.

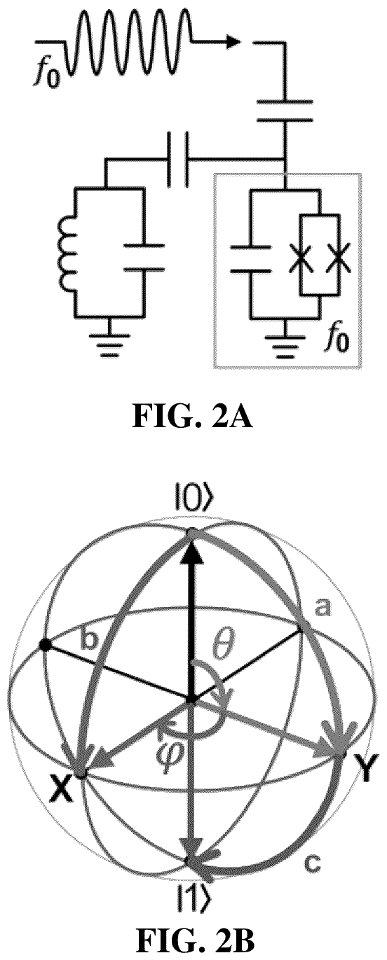

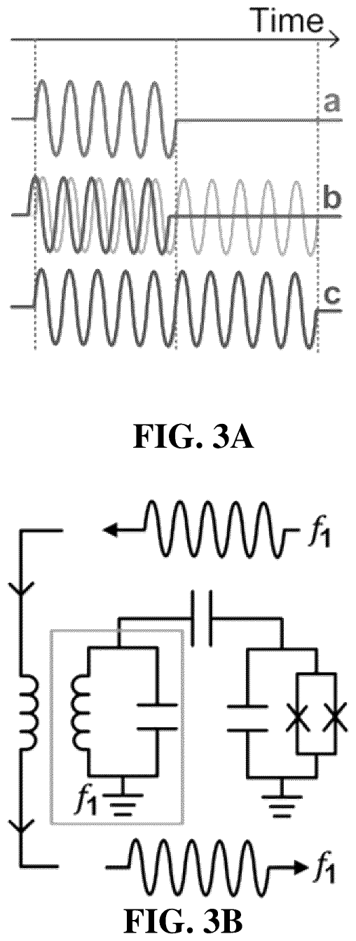

As shown in FIGS. 2A, 2B and 3A, in superconducting qubits, control is achieved through precisely-shaped microwave pulses that induce arbitrary rotations on the Bloch sphere (FIG. 2B), which visually represents the state of a qubit. A qubit's state can be depicted as a point on the Bloch sphere, and controlling the qubit involves rotating this point around the sphere. The phase of the microwave signal applied at the qubit's resonant frequency determines the angle of rotation on the XY-plane, as depicted in FIG. 2A; the total microwave energy determines the amount of rotation that occurs. Typical superconducting qubits are designed with natural frequencies between 4.5 and 6 GHz, with adjacent qubits differing by tens of MHz.

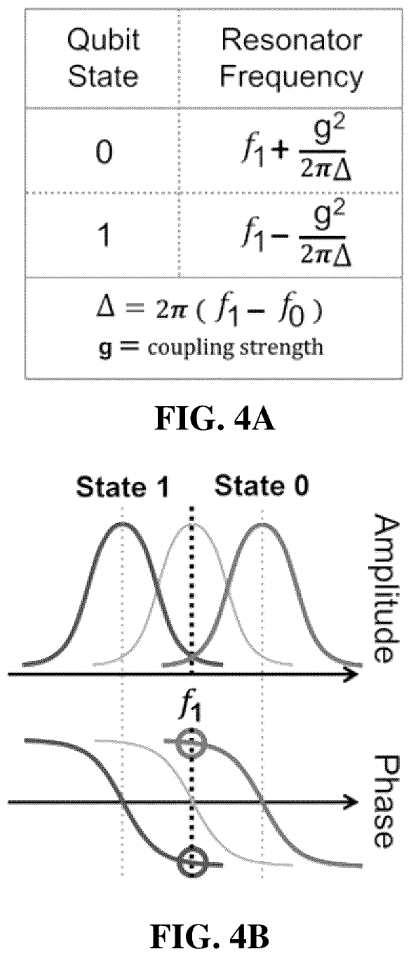

As shown in FIGS. 3B, 4A and 4B, to read out a qubit's state, a separate resonator, tuned between 6.5 and 8 GHz, is used. The qubit's state influences the separate resonator's frequency through dispersive coupling, allowing the qubit state to be inferred by measuring the magnitude or phase of the probing signal interacting with the resonator.

To generate microwave signals at very precise frequencies to control and manipulate qubits, such as superconducting qubits in quantum computing, local oscillators are used. The quantum state of a qubit (typically transitioning between its |0 [symbol] and |1 [symbol] states) is controlled by applying microwave pulses at specific frequencies. These frequencies are extremely stable and precise to ensure high gate fidelity and low error rate. Local oscillator frequencies are the precise frequencies generated by a phase-locked loop device. The phase-locked loop takes a stable reference clock (a low-frequency signal) and multiplies or divides it to generate the desired high frequency local oscillators.

In conventional quantum computing hardware, the most common approach is to have room-temperature local oscillators generate the precise microwave signals to control and manipulate qubits and minimize errors, as qubit operations rely on transitions between specific quantum states, typically |0 [symbol] and |1 [symbol] . Phase-locked loops are commonly used to generate these precise local oscillator frequencies by multiplying or dividing a stable reference clock to produce the desired output. Such traditional approaches involving external local oscillator sources present challenges, however, including that mismatches in external local oscillator feeding can cause local oscillator leakage into the qubit's driving channel, potentially shifting the qubit's state through unwanted near-resonance tones. Superconducting qubits have shorter energy relaxation times (10-100 μs) compared to other qubit types, such as spin-based or trapped-ion qubits, and as a result, qubits have to be driven with short microwave pulses, typically 15-30 ns, allowing many gate operations within their coherence time. However, shorter pulses lead to reduced spectral selectivity and non-negligible spectral leakage. Given the finite anharmonicity separation between qubit energy levels (usually 150-350 MHz), using frequency-division multiplexing (FDM) or time-division multiplexing (TDM) with a single RF cable becomes impractical. A common solution is to assign a dedicated local oscillator to each qubit for pulse modulation, which helps reduce frequency mixing; as a consequence, as the number of qubits grows, the power consumption from these local oscillators risks exceeding the cooling power budget in cryogenic environments.

To overcome such challenges, described herein is operating such components at cryogenic temperatures, along with other considerations. Returning to example system 100 of FIG. 1, RSFQ-based phase-locked loops (PLLs), block 108, are used to generate local oscillators (LOs) internally, avoiding the need for external local oscillator sources that often introduce leakage and noise. Each RSFQ-based phase-locked loop, deployed in the dilution refrigerator 104, generates a separate local oscillator frequency for a group of qubits, helping to ensure that multiple qubits can be controlled without phase drift or frequency interference. This effectively suppresses local oscillator leakage, as the local oscillators are evenly distributed across a wide frequency range, which mitigates the risk of unwanted frequency mixing. The phase-locked loops are synchronized using a common reference clock 110 (e.g., 500 MHz), ensuring that the local oscillators are phase-coherent and operate in unison. This maintains qubit coherence during operations and ensure minimal phase errors in long-duration quantum programs.

Each qubit thus interacts via precise microwave pulses that manipulate the qubit's state on the Bloch sphere (FIG. 2B). CMOS-based pulse modulators 112, also deployed in the dilution refrigerator 104, are responsible for shaping these pulses by modulating the amplitude and phase of the microwave signals generated by the phase-locked loop 108/local oscillators. The pulse modulator 112 takes the local oscillator frequencies provided by the RSFQ-based phase-locked loop(s) 108 and modulates them to create the appropriate control signals for qubit operations. These pulse modulators 112 can be optimized for operation at cryogenic temperatures, as excess heat can destabilize qubit coherence. In one implementation, the modulators 112 create short microwave pulses (~15-30 ns) to control the qubits, taking advantage of the fast-switching speeds of the RSFQ and CMOS technologies.

As set forth herein, the SFQ-Based Repeaters 106 help to ensure high-fidelity signals. More particularly, at lower temperature stages (1 K and below), the SFQ-based repeaters 106 maintain high-fidelity communication between the 4 K control system and the qubit array, deployed at ~10 mK. SFQ technology has advantages over CMOS at these stages due to its superconducting nature, which ensures minimal power dissipation and thermal noise generation.

The system includes RF attenuators 114 and 115 in the control lines, because even with the SFQ repeaters 106, the system uses the RF attenuators 114 and 115 at various stages of the system, following the coprocessor, primarily to prevent overdriving the qubits. In general, the attenuators 114 and 115 reduce the power of the microwave signals, ensuring that only the appropriate amount of energy reaches each qubit. This avoids unintended state transitions or other qubit errors due to excessive signal power. The attenuators 114 and 115 also help with thermal noise management.

Amplifiers are used in the readout line. In one implementation, one or more Josephson parametric amplifiers (JPAs) 116 and HEMT (high electron mobility transistor) amplifiers 117 are used to amplify the relatively weak qubit readout signals at cryogenic temperatures. After the qubit states are measured, the amplifiers 116 and 117 increase the signal strength without adding excessive noise, ensuring that the data can be accurately transmitted to the classical control system 118 at room temperature.

The states of multiple qubits, each with a different resonant frequency, are read using a common microwave feedline, referred to as multiplexed qubit readout. The resonator frequencies are intentionally spaced to ensure minimal interference, and frequency-division multiplexing is used for generally simultaneous qubit readout. This approach significantly reduces the number of cables in the system 100 compared to conventional quantum hardware.

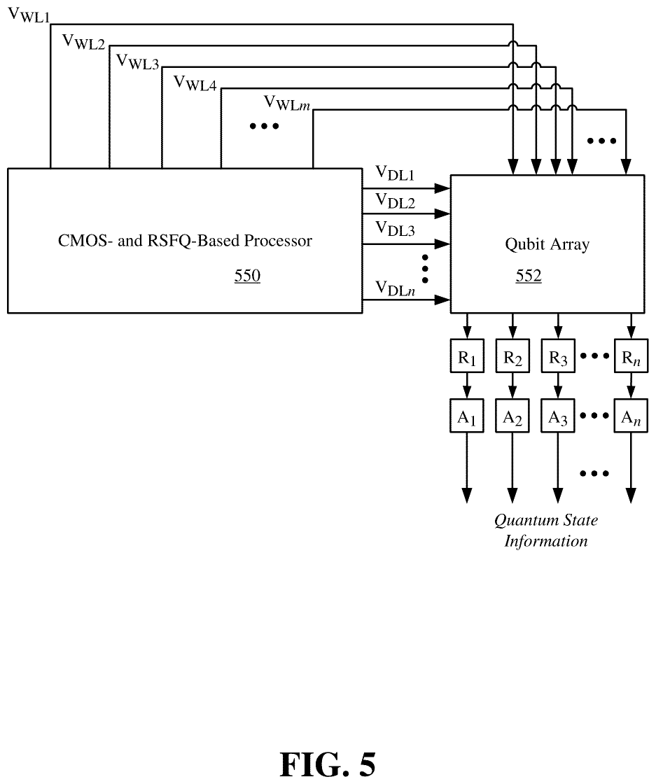

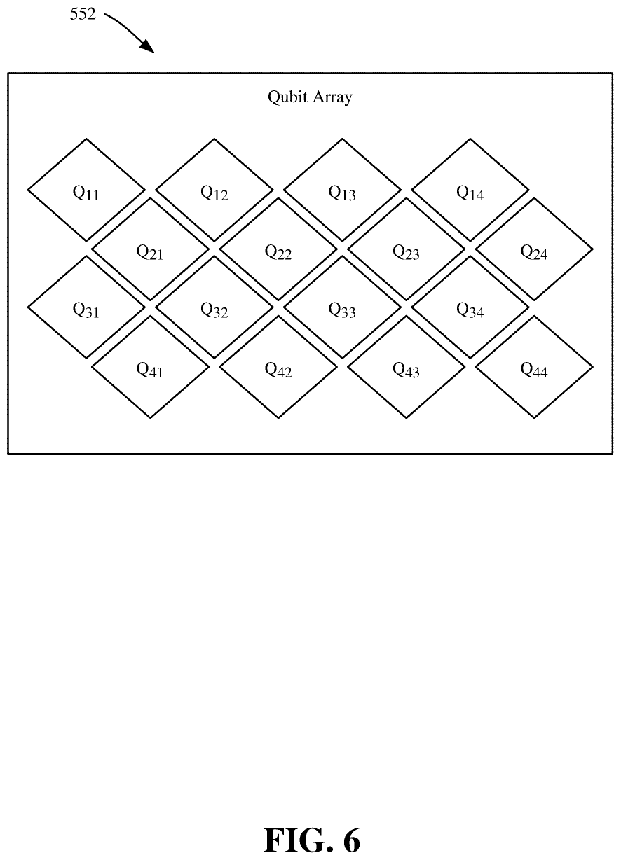

FIGS. 5 and 6 show how a CMOS-and RSFQ-based processor 550, which can include or be coupled to a multiplexer and so on, can address any qubit in the n×m array qubit array 552 by applying a sufficient bias voltage to a selected word line of the word lines V_{WL1}-V_{WLm}, and a selected data line of the data lines V_{DL1}-V_{DLn}. Readout is via the resonators R₁-Rₙ, typically along with some amplification (e.g., amplifiers A₁-Aₙ).

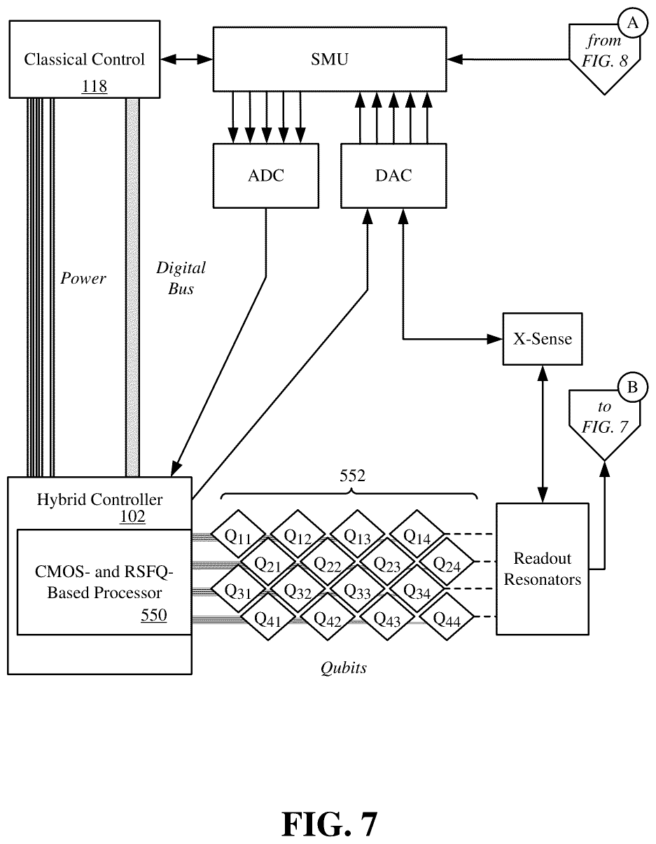

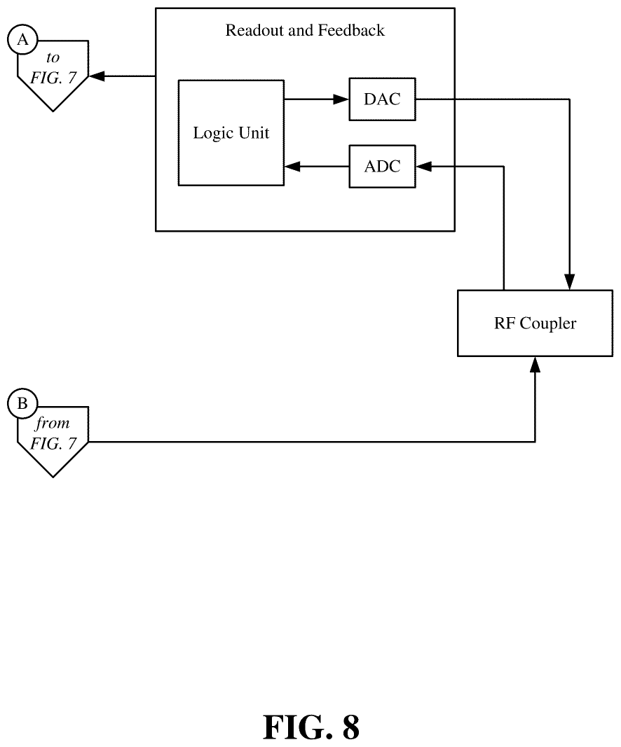

For cryogenic feedback and error correction, a cryogenic receiver 120 is collocated with the waveform generation components 108 and 112 at the 4K stage. After the qubit measurements are processed, a logic unit in the cryogenic receiver provides low-latency feedback to the qubit array to stabilize the system, as shown in FIGS. 7 and 8. Digital to analog controllers 770

In general, as shown in FIGS. 7 and 8, digital-to-analog converters (DACs) along with analog-to-digital converters (ADC) translate between the digital signals used for classical computation and the analog signals used in the quantum hardware. For example, the ADC digitizes the analog signals received from the qubit measurement. A digital source measure unit (SMU) can provide precise voltage or current control for various elements in the quantum system. The SMU ensures that bias voltages and other control parameters are stable, which maintains qubit fidelity. Such a hardware-level feedback device facilitates real-time error tracking and correction, which helps in achieving fault-tolerant quantum computing.

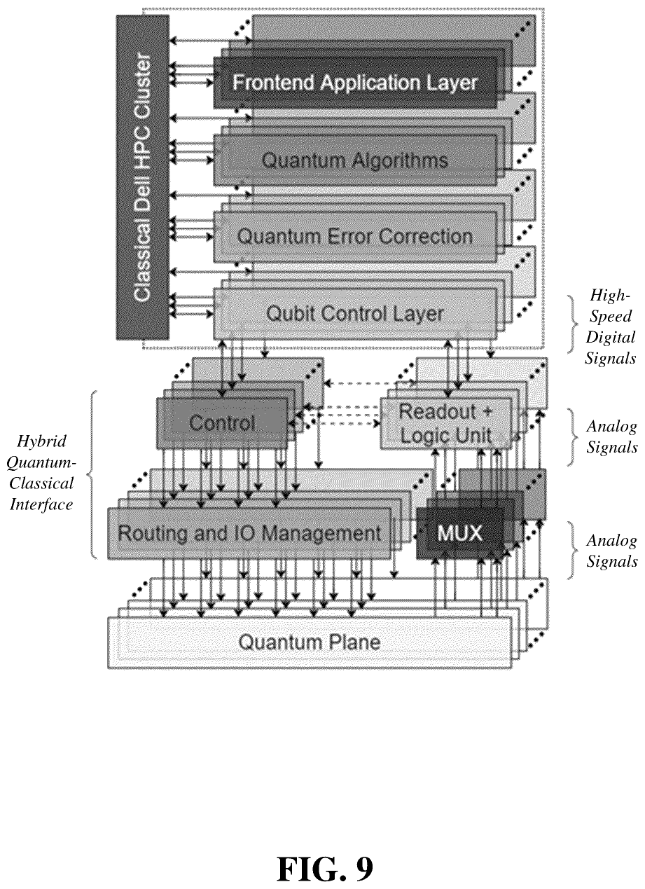

Thus, in the system 100, the hybrid controller 102 integrates with a classical high-performance computing (HPC) cluster or server (classical control 118). This integration can be via a frontend application layer, shown in FIG. 9. The interface manages the high-speed digital signals needed for quantum algorithms and error correction, while routing the analog signals for qubit control and readout through specialized layers. For example, there is a qubit control layer, a layer for quantum programs algorithms, and a layer for error correction systems. High-speed digital and analog signals are touted and managed through the hybrid quantum-classical interface. The coprocessor can use RSFQ logic to process qubit measurement results and provide feedback to the quantum system, ensuring low-latency operations.

One or more example implementations and embodiments can be embodied in a system, such as described and represented herein. The system can include a cryogenic phase locked loop device deployed in a dilution refrigerator at a cryogenic temperature. The phase locked loop device can be configured to generate a local oscillator frequency corresponding to a microwave pulse. The system can include a cryogenic pulse modulator deployed in the dilution refrigerator at the cryogenic temperature; the pulse modulator can be configured to modulate at least one of an amplitude or a phase of the microwave pulse to shape the microwave pulse, resulting in a microwave signal for interaction with a qubit. The system can include a cryogenic receiver configured to obtain qubit measurement data, representative of at least one measurement taken with respect to the qubit, from the qubit following interaction of the qubit with the microwave signal.

The cryogenic phase locked loop device can include rapid single flux quantum-based logic, and the cryogenic pulse modulator can include a complementary metal oxide transistor-based device.

The cryogenic phase locked loop device, the cryogenic pulse modulator, and the cryogenic receiver can be deployed in a dilution refrigerator at a first temperature level, and the group of qubits can be deployed in the dilution refrigerator at a second temperature level. The first temperature level can be about five Kelvin or below, and the second temperature level can be about ten milli-Kelvin or below.

The cryogenic pulse modulator can be coupled to the qubit via at least one attenuator deployed between the cryogenic pulse modulator and the qubit.

The cryogenic pulse modulator can be coupled to the qubit via at least one repeater deployed between the cryogenic pulse modulator and the qubit.

The cryogenic receiver can be coupled to a resonator coupled to the qubit to obtain the qubit measurement data from the qubit.

The qubit can include one qubit of a group of respective qubits, the resonator can include one resonator of a group of respective resonators having different respective resonance frequencies, and the cryogenic receiver obtains respective qubit measurement data, representative of respective measurements taken with respect to the respective qubits, from the respective qubits via frequency-division multiplexing of the respective resonators coupled to a common microwave feedline and to the cryogenic receiver.

The cryogenic receiver can be coupled to the resonator via a circulator and at least one amplifier.

The cryogenic receiver can be coupled to the resonator via a Josephson parametric amplifier.

The cryogenic receiver can be coupled to the resonator via a high-electron-mobility transistor.

The cryogenic receiver can be communicatively coupled to a non-quantum computing device.

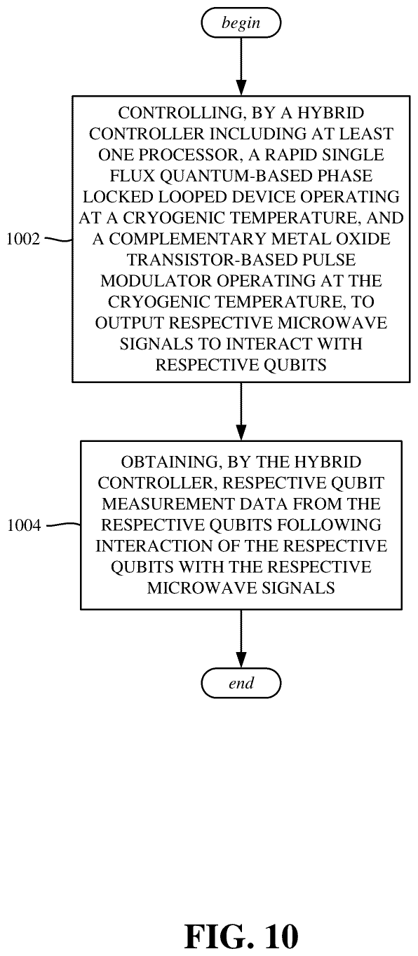

One or more example implementations and embodiments, such as corresponding to example operations of a method, can be represented in FIG. 10. Example operation 1002 represents controlling, by a hybrid controller including at least one processor, a rapid single flux quantum-based phase locked looped device operating at a cryogenic temperature, and a complementary metal oxide transistor-based pulse modulator operating at the cryogenic temperature, to output respective microwave signals to interact with respective qubits. Example operation 1004 represents obtaining, by the hybrid controller, respective qubit measurement data from the respective qubits following interaction of the respective qubits with the respective microwave signals.

A cryogenic receiver of the hybrid controller can be coupled to respective resonators having different respective resonance frequencies via a common microwave feedline, and obtaining the respective qubit measurement data can include resonating the respective resonators at the different respective resonance frequencies to couple the respective qubit measurement data of the respective qubits to the respective resonators coupled to the common microwave feedline via multiplexed qubit readout. Qubit measurement data associated with a qubit of the respective qubits can indicate an error state of the qubit, and further operations can include controlling, by the hybrid controller, the rapid single flux quantum-based phase locked looped device and the pulse modulator to output a corrective microwave signal to interact with the qubit.

Further operations can include communicating, by the hybrid controller, with a computing device to execute a quantum program on at least some of the respective qubits via interaction with the qubits using at least some of the respective microwave signals.

One or more example implementations and embodiments can be embodied in a system, such as described and represented herein. The system can include a hybrid controller deployed in a dilution refrigerator at a cryogenic temperature. The hybrid controller can include a rapid single flux quantum-based phase locked loop device configured to generate local oscillator frequencies corresponding to microwave pulses, and a complementary metal oxide transistor-based pulse modulator configured to modulate at least one of an amplitude or a phase of the microwave pulses to shape the microwave pulses, resulting in respective microwave signals for interaction with respective qubits. The system can include a first readout resonator coupled to a first qubit of the respective qubits, the first readout resonator configured to resonate at a first frequency to obtain first qubit measurement data from the first qubit, and a second readout resonator coupled to a second qubit of the respective qubits, the second readout resonator configured to resonate at a second frequency to obtain second qubit measurement data from the second qubit, wherein the first frequency can be different from the second frequency.

The complementary metal oxide transistor-based pulse modulator can be coupled to the respective qubits via respective first attenuators, respective second attenuators, and respective single-flux quantum-based repeaters deployed between the respective first attenuators and the respective second attenuators.

The hybrid controller can further include a receiver, and the first readout resonator and the second resonator can be coupled to the receiver via a common microwave feedline.

The hybrid controller further can include a receiver, and wherein the first readout resonator and the second resonator can be coupled to the receiver via a circulator, a Josephson parametric amplifier, and a high-electron-mobility transistor.

As can be seen, the technology described herein facilitates a scalable platform for controlling a large number of qubits with reduced power consumption and heat dissipation. The technology integrates RSFQ-based Phase Locked Loops (PLLs) and CMOS based pulse modulators, providing low-noise, high-speed and precise waveform generation for qubit operations. SFQ-based repeaters are deployed at subsequent cryogenic stages after the pulses are generated, to maintain signal integrity and allow low-latency communication between the controller and the qubits. SFQ-technology for the repeaters helps ensure minimal power dissipation and prevent heat-induced qubit decoherence. Further, a logic unit in the cryogenic receiver processes qubit measurement data and provides virtually immediate feedback to the waveform generation section, which allows for rapid correction of errors such as leakage and decoherence. Still further, the technology described herein avoids the current approach of having per-qubit control lines.

The above description of illustrated embodiments of the subject disclosure, comprising what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

As used in this application, the terms “component,” “system,” “platform,” “layer,” “selector,” “interface,” and the like are intended to refer to a computer-related resource or an entity related to an operational apparatus with one or more specific functionalities, wherein the entity can be either hardware, a combination of hardware and software, software, or software in execution. As an example, a component can be an apparatus with specific functionality provided by mechanical parts operated by electric or electronic circuitry. As yet another example, a component can be an apparatus that provides specific functionality through electronic components without mechanical parts, the electronic components can comprise a processor therein to execute software or firmware that confers at least in part the functionality of the electronic components.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances.

While the embodiments are susceptible to various modifications and alternative constructions, certain illustrated implementations thereof are shown in the drawings and have been described above in detail. It should be understood, however, that there is no intention to limit the various embodiments to the specific forms disclosed, but on the contrary, the intention is to cover all modifications, alternative constructions, and equivalents falling within the spirit and scope.

In addition to the various implementations described herein, it is to be understood that other similar implementations can be used or modifications and additions can be made to the described implementation(s) for performing the same or equivalent function of the corresponding implementation(s) without deviating therefrom. Still further, multiple processing chips or multiple devices can share the performance of one or more functions described herein, and similarly, storage can be effected across a plurality of devices. Accordingly, the various embodiments are not to be limited to any single implementation, but rather are to be construed in breadth, spirit, and scope in accordance with the appended claims.

What is claimed is:

1. A system, comprising:
a cryogenic phase locked loop device deployed in a dilution refrigerator at a cryogenic temperature, the phase locked loop device configured to generate a local oscillator frequency corresponding to a microwave pulse;
a cryogenic pulse modulator deployed in the dilution refrigerator at the cryogenic temperature, the pulse modulator configured to modulate at least one of an amplitude or a phase of the microwave pulse to shape the microwave pulse, resulting in a microwave signal for interaction with a qubit; and
a cryogenic receiver configured to obtain qubit measurement data, representative of at least one measurement taken with respect to the qubit, from the qubit following interaction of the qubit with the microwave signal.

2. The system of claim 1, wherein the cryogenic phase locked loop device comprises rapid single flux quantum-based logic, and wherein the cryogenic pulse modulator comprises a complementary metal oxide transistor-based device.

3. The system of claim 1, wherein the cryogenic phase locked loop device, the cryogenic pulse modulator, and the cryogenic receiver are deployed in a dilution refrigerator at a first temperature level, and wherein the group of qubits is deployed in the dilution refrigerator at a second temperature level.

4. The system of claim 3, wherein the first temperature level is about five Kelvin or below, and wherein the second temperature level is about ten milli-Kelvin or below.

5. The system of claim 1, wherein the cryogenic pulse modulator is coupled to the qubit via at least one attenuator deployed between the cryogenic pulse modulator and the qubit.

6. The system of claim 1, wherein the cryogenic pulse modulator is coupled to the qubit via at least one repeater deployed between the cryogenic pulse modulator and the qubit.

7. The system of claim 1, wherein the cryogenic receiver is coupled to a resonator coupled to the qubit to obtain the qubit measurement data from the qubit.

8. The system of claim 1, wherein the qubit comprises one qubit of a group of respective qubits, wherein the resonator comprises one resonator of a group of respective resonators having different respective resonance frequencies, and wherein the cryogenic receiver obtains respective qubit measurement data, representative of respective measurements taken with respect to the respective qubits, from the respective qubits via frequency-division multiplexing of the respective resonators coupled to a common microwave feedline and to the cryogenic receiver.

9. The system of claim 1, wherein the cryogenic receiver is coupled to the resonator via a circulator and at least one amplifier.

10. The system of claim 1, wherein the cryogenic receiver is coupled to the resonator via a Josephson parametric amplifier.

11. The system of claim 1, wherein the cryogenic receiver is coupled to the resonator via a high-electron-mobility transistor.

12. The system of claim 1, wherein the cryogenic receiver is communicatively coupled to a non-quantum computing device.

13. A method, comprising:
controlling, by a hybrid controller comprising at least one processor, a rapid single flux quantum-based phase locked looped device operating at a cryogenic temperature, and a complementary metal oxide transistor-based pulse modulator operating at the cryogenic temperature, to output respective microwave signals to interact with respective qubits; and
obtaining, by the hybrid controller, respective qubit measurement data from the respective qubits following interaction of the respective qubits with the respective microwave signals.

14. The method of claim 13, wherein a cryogenic receiver of the hybrid controller is coupled to respective resonators having different respective resonance frequencies via a common microwave feedline, and wherein the obtaining of the respective qubit measurement data comprises resonating the respective resonators at the different respective resonance frequencies to couple the respective qubit measurement data of the respective qubits to the respective resonators coupled to the common microwave feedline via multiplexed qubit readout.

15. The method of claim 14, wherein qubit measurement data associated with a qubit of the respective qubits indicates an error state of the qubit, and further comprising controlling, by the hybrid controller, the rapid single flux quantum-based phase locked looped device and the pulse modulator to output a corrective microwave signal to interact with the qubit.

16. The method of claim 13, further comprising communicating, by the hybrid controller, with a computing device to execute a quantum program on at least some of the respective qubits via interaction with the qubits using at least some of the respective microwave signals.

17. A system, comprising:
a hybrid controller deployed in a dilution refrigerator at a cryogenic temperature, the hybrid controller comprising:
a rapid single flux quantum-based phase locked loop device configured to generate local oscillator frequencies corresponding to microwave pulses; and
a complementary metal oxide transistor-based pulse modulator configured to modulate at least one of an amplitude or a phase of the microwave pulses to shape the microwave pulses, resulting in respective microwave signals for interaction with respective qubits;
a first readout resonator coupled to a first qubit of the respective qubits, the first readout resonator configured to resonate at a first frequency to obtain first qubit measurement data from the first qubit; and
a second readout resonator coupled to a second qubit of the respective qubits, the second readout resonator configured to resonate at a second frequency to obtain second qubit measurement data from the second qubit, wherein the first frequency is different from the second frequency.

18. The system of claim 17, wherein the complementary metal oxide transistor-based pulse modulator is coupled to the respective qubits via respective first attenuators, respective second attenuators, and respective single-flux quantum-based repeaters deployed between the respective first attenuators and the respective second attenuators.

19. The system of claim 17, wherein the hybrid controller further comprises a receiver, and wherein the first readout resonator and the second resonator are coupled to the receiver via a common microwave feedline.

20. The system of claim 17, wherein the hybrid controller further comprises a receiver, and wherein the first readout resonator and the second resonator are coupled to the receiver via a circulator, a Josephson parametric amplifier, and a high-electron-mobility transistor.
